(19) United States
(12) Patent Application Publication
(10) Pub. No.: US 2008/0031376 A1
(43) Pub. Date: Feb. 7, 2008

(54) TRANSMISSION APPARATUS, RECEPTION APPARATUS AND RADIO COMMUNICATION SYSTEM

(75) Inventor: Koichiro BAN, Kawasaki-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/781,473

(22) Filed: Jul. 23, 2007

(30) Foreign Application Priority Data
Aug. 4, 2006 (JP) 2006-213646

(51) Int. Cl. H03K 7/06; H03K 9/06

(52) U.S. Cl. 375/271

(57) ABSTRACT

There is provided with a transmission apparatus including: a first modulator configured to perform modulation processing on data to be transmitted to a first reception apparatus and thereby generate amplitude-phase data made up of data of amplitude and phase; a second modulator configured to perform modulation processing so as to decompose data to be transmitted to a second reception apparatus into a plurality of frequency components and thereby generate frequency data which is data on a frequency domain; and a transmitter configured to allocate the amplitude-phase data to first subcarriers out of a plurality of subcarriers and allocate the frequency data to second subcarriers which are different from the first subcarriers out of the plurality of subcarriers, thereby generate subcarrier data and transmit generated subcarrier data to the first reception apparatus and the second reception apparatus.

### CROSS REFERENCE TO RELATED APPLICATIONS

This application is based upon and claims the benefit of priority from the prior Japanese Patent Applications No. 2006-213646 filed on Aug. 4, 2006, the entire contents of which are incorporated herein by reference.

### BACKGROUND OF THE INVENTION

1. Field of the Invention

The present invention relates to the configuration of a transmitter and a receiver in a radio communication system, and more particularly, to the configuration of a transmitter and a receiver when there is a mixture of an OFDM scheme and a single carrier scheme.

2. Related Art

Conventionally, there is a method based on a mixture of an OFDM scheme and a single carrier scheme that uses the OFDM scheme for a downlink and the single carrier scheme for an uplink (e.g., see IP-A 2000-174725 (Kokai)).

There is also an OFDM transmitter that performs transmission to a single carrier receiver using two subcarriers located near the center out of subcarriers within a certain range (e.g., see IP-A 2000-151547 (Kokai)).

Such conventional schemes have a problem that the OFDM scheme and the single carrier scheme cannot be used at the same time. Furthermore, there is another problem that only two subcarriers can be used when transmission is performed from the OFDM transmitter to the single carrier receiver. Moreover, there is a further problem that the OFDM scheme and the single carrier scheme cannot coexist without any interference.

### SUMMARY OF THE INVENTION

According to an aspect of the present invention, there is provided with a transmission apparatus comprising:

a first modulator configured to perform modulation processing on data to be transmitted to a first reception apparatus and thereby generate amplitude-phase data made up of data of amplitude and phase;

a second modulator configured to perform modulation processing so as to decompose data to be transmitted to a second reception apparatus into a plurality of frequency components and thereby generate frequency data which is data on a frequency domain; and

a transmitter configured to allocate the amplitude-phase data to first subcarriers out of a plurality of subcarriers and allocate the frequency data to second subcarriers which are different from the first subcarriers out of the plurality of subcarriers, thereby generate subcarrier data and transmit generated subcarrier data to the first reception apparatus and the second reception apparatus.

According to an aspect of the present invention, there is provided with a transmission apparatus comprising:

a data modulator configured to generate amplitude-phase data made up of data of amplitude and phase by applying modulation processing to data to be transmitted;

a data expander configured to generate expanded data by adding part of the amplitude-phase data to a head and an end of the amplitude-phase data to extend the amplitude-phase data;

an upsampling unit configured to obtain upsampled data by inserting predetermined data between symbols forming the expanded data to perform upsampling;

a filter processor configured to obtain filter processed data by performing waveform shaping filter processing on the upsampled data;

a remover configured to obtain removed data by removing parts at a head and an end of the filter processed data; and

an adder configured to copy part of an end of the removed data and adding copied part to a head of the removed data.

According to an aspect of the present invention, there is provided with a transmission apparatus comprising:

a data modulator configured to generate amplitude-phase data made up of data of amplitude and phase by applying modulation processing to data to be transmitted;

an upsampling unit configured to obtain upsampled data by inserting predetermined data between symbols forming the amplitude-phase data to perform upsampling;

a filter processor configured to obtain filter processed data by performing waveform shaping filter processing on the upsampled data;

an adder configured to obtain addition data by adding parts at a head and an end of the filter processed data to specific data portion excluding the parts at the head and the end in the filter processed data; and

an adder configured to copy part at an end of the addition data and add copied part to a head of the addition data.

According to an aspect of the present invention, there is provided with a reception apparatus comprising:

a Fourier transformer configured to obtain frequency domain data made up of a plurality of frequency components by performing a Fourier transform on a received signal;

a divider configured to divide the frequency domain data into first frequency domain data which corresponds to third subcarriers out of a plurality of subcarriers and second frequency domain data which corresponds to fourth subcarriers which are different from the third subcarriers out of the plurality of subcarriers;

a first demodulator configured to demodulate the first frequency domain data in a multicarrier scheme; and

a second demodulator configured to perform demodulation processing on the second frequency domain data to convert the second frequency domain data to data on a time domain.

According to an aspect of the present invention, there is provided with a radio communication system in which a base station using a multicarrier modulation scheme as a modulation scheme, a multicarrier terminal apparatus using the multicarrier modulation scheme, and a terminal apparatus using a single carrier modulation scheme are wirelessly connected, comprising:

wherein the base station includes;

a base station transmitter having
a first modulator configured to perform modulation processing on data to be transmitted to the multicarrier terminal apparatus and thereby generate amplitude-phase data made up of data of amplitude and phase,
a second modulator configured to perform modulation processing so as to decompose data to be transmitted to the terminal apparatus into a plurality of frequency components and thereby generate frequency data which is data on a frequency domain, and
a transmitter configured to allocate the amplitude-phase data to first subcarriers used by the multicarrier terminal apparatus out of a plurality of subcarriers and allocate the frequency data to second subcarriers used by the terminal apparatus which are different from the first subcarriers out of the plurality of subcarriers, thereby generate subcarrier data and transmit generated subcarrier data to the multicarrier terminal apparatus and the terminal apparatus,

a base station receiver having
a Fourier transformer configured to obtain frequency domain data made up of a plurality of frequency components by performing a Fourier transform on a received signal;
a divider configured to divide the frequency domain data into first frequency domain data which corresponds to third subcarriers used by the multicarrier terminal apparatus out of a plurality of subcarriers and second frequency domain data which corresponds to fourth subcarriers used by the terminal apparatus which are different from the third subcarriers out of the plurality of subcarriers;
a first demodulator configured to demodulate the first frequency domain data in a multicarrier scheme; and
a second demodulator configured to perform demodulation processing on the second frequency domain data to convert the second frequency domain data to data on a time domain,

the multicarrier terminal apparatus includes;

a multicarrier terminal transmitter
configured to obtain modulated data by performing modulation processing on data to be transmitted to the base station in the multicarrier modulation scheme,
configured to copy part of an end of the modulated data, add copied part to a head of the modulated data as a cyclic prefix and thereby obtain modulated data with the cyclic prefix, and
configured to transmit the modulated data with the cyclic prefix, and

a multicarrier terminal receiver configured to performing demodulation processing on a received signal from the base station in a multicarrier demodulation scheme corresponding to the multicarrier modulation scheme, and

the terminal apparatus includes;

a terminal transmitter having
a data modulator configured to generate amplitude-phase data made up of data of amplitude and phase by applying modulation processing to data to be transmitted to the base station;
a data expander configured to generate expanded data by adding part of the amplitude-phase data to a head and an end of the amplitude-phase data to extend the amplitude-phase data;
an upsampling unit configured to obtain upsampled data by inserting predetermined data between symbols forming the expanded data to perform upsampling;
a filter processor configured to obtain filter processed data by performing waveform shaping filter processing on the upsampled data;
a remover configured to obtain removed data by removing parts at a head and an end of the filter processed data; and
an adder configured to copy part of an end of the removed data and adding copied part to a head of the removed data as a cyclic prefix, and

a terminal receiver configured to performing predetermined demodulation processing on a received signal from the base staion, and

wherein a length of the cyclic prefix added by the adder of the terminal apparatus is equal to a length of the cyclic prefix added by the multicarrier terminal transmitter of the multicarrier terminal apparatus.

### BRIEF DESCRIPTION OF THE DRAWINGS

FIG. 1 shows a configuration example of a radio communication system including an OFDM transmitter, single carrier receiver and OFDM receiver according to an embodiment of the present invention;

FIG. 2 illustrates an example of subcarrier allocation by the OFDM transmitter according to the embodiment of the present invention;

FIG. 3 illustrates a configuration example of the OFDM transmitter which simultaneously transmits data to the single carrier receiver and the OFDM receiver according to the embodiment of the present invention;

FIG. 4 illustrates a configuration example of the single carrier signal modulator of the OFDM transmitter according to the embodiment of the present invention;

FIG. 5 illustrates an example of conversion of a data stream by the aliasing generator of the OFDM transmitter according to the embodiment of the present invention;

FIG. 6 illustrates an example of the single carrier transmitter;

FIG. 7 illustrates a configuration example of the single carrier receiver according to the embodiment of the present invention;

FIG. 8 illustrates an example of a first data stream of the OFDM transmitter according to the embodiment of the present invention;

FIG. 9 illustrates a configuration example of the OFDM receiver according to the embodiment of the present invention;

FIG. 10 illustrates a configuration example of the radio communication system including the OFDM transmitter, single carrier transmitter and OFDM receiver according to the embodiment of the present invention;

FIG. 11 illustrates an example of frequency utilization by the OFDM transmitter and the single carrier transmitter according to the embodiment of the present invention;

FIG. 12 illustrates a first configuration example of the single carrier transmitter according to the embodiment of the present invention;

FIG. 13 illustrates an example of conversion of a data stream by the aliasing adder of the single carrier transmitter according to the embodiment of the present invention;

FIG. 14 illustrates an example of conversion of a data stream by the aliasing processor in the first configuration example of the single carrier transmitter according to the embodiment of the present invention;

FIG. 15 illustrates a second configuration example of the single carrier transmitter according to the embodiment of the present invention;

FIG. 16 illustrates an example of conversion of a data stream by the aliasing adder in a second configuration example of the single carrier transmitter according to the embodiment of the present invention;

FIG. 17 illustrates a third configuration example of the single carrier transmitter according to the embodiment of the present invention;

FIG. 18 illustrates the operation of the aliasing adder of the single carrier transmitter according to the embodiment of the present invention;

FIG. 19 illustrates a fourth configuration example of the single carrier transmitter according to the embodiment of the present invention;

FIG. 20 illustrates a configuration example of the OFDM transmitter according to the embodiment of the present invention;

FIG. 21 illustrates a relationship between a signal from the single carrier transmitter and data length of a signal from the OFDM transmitter according to the embodiment of the present invention;

FIG. 22 illustrates a configuration example of the OFDM receiver which simultaneously receives signals from the single carrier transmitter and the OFDM transmitter according to the embodiment of the present invention;

FIG. 23 illustrates a configuration example of subcarriers of the OFDM receiver according to the embodiment of the present invention;

FIG. 24 illustrates a configuration example of the single carrier signal demodulator of the OFDM receiver according to the embodiment of the present invention; and

FIG. 25 illustrates an example of combining of aliasing data by the aliasing processor of the OFDM receiver according to the embodiment of the present invention.

### DETAILED DESCRIPTION OF THE INVENTION

Hereafter, an embodiment of the present invention will be described in detail with reference to the drawings.

A radio communication system according to this embodiment includes a base station using an OFDM scheme as the transmission scheme (hereinafter, this will be referred to as an “OFDM base station”), a high-speed communication user terminal using an OFDM scheme (hereinafter, this will be referred to as an “OFDM terminal”) and a low-speed communication user terminal using a single carrier scheme such as an voice-only terminal (hereinafter, this will be referred to as an “single carrier terminal”).

The OFDM scheme allows processing on the frequency domain, and therefore it is suitable for a wideband, high transmission rate radio communication system. However, since the OFDM transmitter and the OFDM receiver require an FFT circuit, the cost and the size of the user terminal tend to increase.

There is a demand that such an OFDM radio communication system should accommodate a user terminal having a not so high transmission rate and a lowest possible price such as an voice-only terminal. Satisfying such a demand requires not only a high-price OFDM terminal but also an OFDM radio communication system not requiring any FFT circuit and capable of accommodating a low-price single carrier terminal at the same time.

This embodiment proposes a radio communication system in which the OFDM base station can communicate with not only an OFDM terminal but also a single carrier terminal at the same time. Such a radio communication system will be explained below. Here, a downlink link in a case where a radio signal is transmitted from the OFDM base station to the OFDM terminal and the single carrier terminal will be explained first.

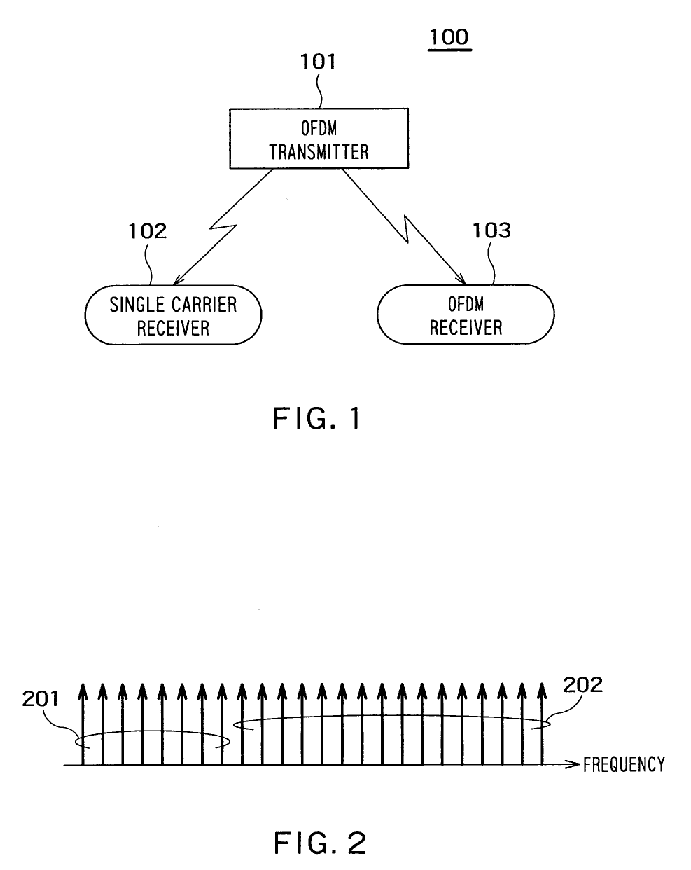

FIG. 1 illustrates a configuration example of a radio communication system 100 according to this embodiment and this radio communication system 100 includes a single carrier receiver (second reception apparatus) 102 using a single carrier scheme, an OFDM receiver 103 (first reception apparatus) using an OFDM scheme and an OFDM transmitter 101 which simultaneously transmits data to the single carrier receiver 102 and the OFDM receiver 103.

As shown in FIG. 2, the OFDM transmitter 101 transmits data to the single carrier receiver 102 using some subcarriers (second subcarriers) 201 of all subcarriers and transmits data to the OFDM receiver 103 using other subcarriers (first subcarriers) 202. One arrow in the figure indicates one subcarrier. The numbers of the second subcarriers 201 is less than those of the first subcarriers 202, for example.

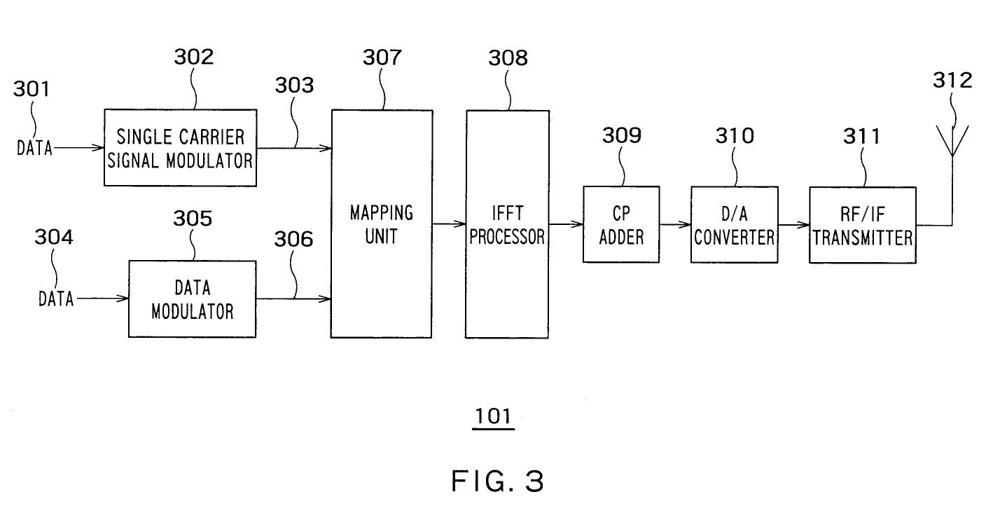

FIG. 3 shows a configuration example of the OFDM transmitter 101 according to this embodiment which simultaneously transmits data to the single carrier receiver 102 and the OFDM receiver 103. A first data stream 301 which is transmission data to the single carrier receiver 102 is converted to a frequency data stream 303 by a single carrier signal modulator (second modulator) 302.

In this case, the single carrier signal modulator 302 converts the first data stream 301 to the frequency data stream 303 so that the signal waveform of the first data stream 301 transmitted from the OFDM transmitter 101 has substantially the same signal waveform generated by the single carrier transmitter. This allows the single carrier receiver 102 to receive this first data stream 301.

On the other hand, a second data stream 304 which is transmission data to the OFDM receiver 103 is modulated into a second modulated data stream 306 at a data modulator (first modulator) 305. The second modulated data stream 306 is a vector of signal points in phase-amplitude modulation such as QPSK and QAM.

Next, a mapping unit 307 maps the frequency data stream 303 and the second modulated data stream 306 to different subcarriers. For example, as shown in FIG. 2, the mapping unit 307 allocates subcarrier some subcarriers 201 out of all the subcarriers to the frequency data stream 303 and allocates other subcarriers 202 to the second modulated data stream 306.

The data (subcarrier data) output from the mapping unit 307 is collectively subjected to IFFT processing at an IFFT (inverse fast Fourier transform) processor 308 and thereby converted to a data stream on the time domain. With a cyclic prefix added thereto by a CP adder 309, this data stream on the time domain is converted to an analog signal by a D/A converter 310 and then transmitted from an antenna 312 through an RF/IF transmitter 311. The mapping unit 307, IFFT processor 308, CP adder 309, D/A converter 310, RF/IF transmitter 311 and antenna 312 constitute a transmitter.

In this way, one OFDM symbol transmitted from the OFDM transmitter 101 includes the first data stream 301 and the second data stream 304.

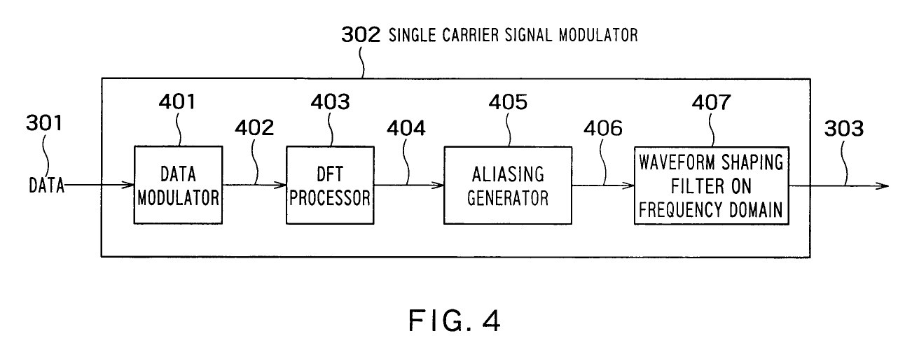

FIG. 4 illustrates the configuration of the single carrier signal modulator 302 which generates the frequency data stream 303. A data modulator 401 converts the first data stream 301 to a first modulated data stream 402 having a length of N (N is a positive integer) made up of signal point vectors representing phase-amplitude modulation such as QPSK and QAM. This causes the OFDM transmitter 101 to transmit N modulated data symbols per 1 OFDM symbol time to the single carrier receiver 102.

A DFT (discrete Fourier transform) processor 403 generates a DFT output data stream 404 having a length of N by converting the first modulated data stream 402 from a time domain signal to a frequency domain signal.

An aliasing generator 405 (data expander) converts the DFT output data stream 404 to an aliasing data stream 406 having a length of M (M is an integer equal to or greater than N). Here, “M” indicates the frequency width of a waveform shaping filter 407 on the frequency domain expressed in subcarrier units and indicates the number of subcarriers occupied by the single carrier signal. That is, the number of subcarriers occupied by the frequency data stream 303 is M.

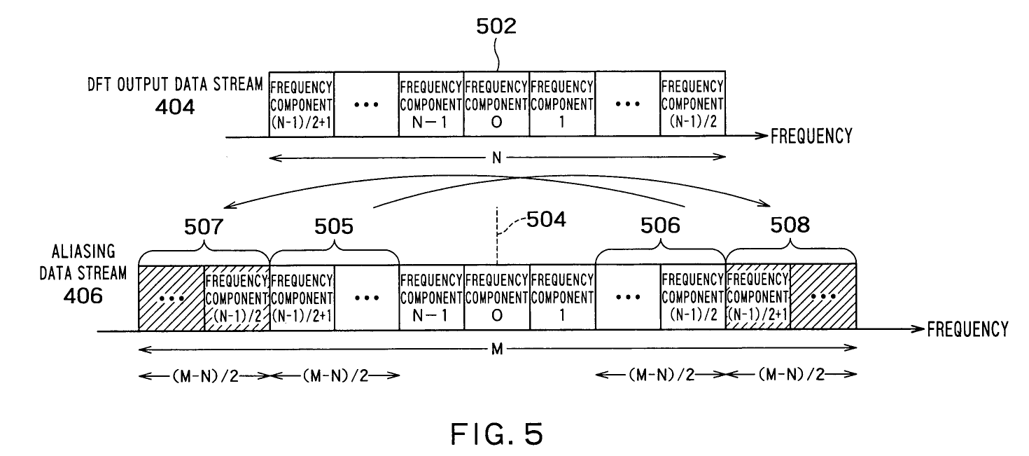

FIG. 5 shows an example of expansion (aliasing processing) of the DFT output data stream 404 by the aliasing generator 405. It is an aliasing data stream 406, which is an output signal of the aliasing generator 405 that results from a conversion of a data stream obtained by repeating the DFT output data stream 404 arranged centered on a DC component 502 to M elements of data centered on a central frequency 504 of the waveform shaping filter 407.

That is, the aliasing data stream 406 having a length of M is generated by adding first (M−N)/2 elements of data 505 to the rear end of the DFT output data stream 404 having a length of N and adding last (M−N)/2 elements of data 506 of the DFT output data stream 404 to the head of the DFT output data stream 404.

Since the waveform shaping filter 407 is normally symmetric with respect to the DC component 502, the number of elements of data 507 added to the head is the same as the number of elements of data 508 added to the end thereof, but depending on the central frequency and the shape of the waveform shaping filter 407, different numbers of elements of data may be added to the head and the end. When “M−N” is an odd number, it is also possible to add (M−N+1)/2 elements of data to the head and add (M−N−1)/2 elements of data to the end or add (M−N−1)/2 elements of data to the head and add (M−N+1)/2 elements of data to the end.

Next, the waveform shaping filter 407 on the frequency domain generates a frequency data stream 303 having a length of M by multiplying the aliasing data stream 406 having a length of M by filter coefficients. A root roll-off filter or roll-off filter may be used for the waveform shaping filter 407. The waveform shaping filter processing on the frequency domain does not refer to convolution but processing of multiplying each element of the aliasing data stream 406 by a complex number.

The processing of carrying out aliasing processing and waveform shaping filter processing on a DFT-processed signal on the frequency domain is substantially the same processing as the waveform shaping filter processing which has the same characteristic on the time domain.

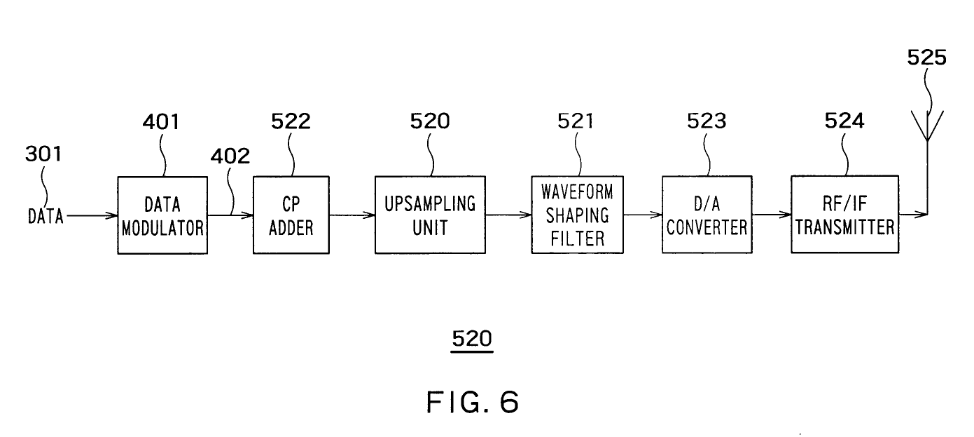

Therefore, according to the OFDM transmitter 101 of this embodiment, it is possible to generate substantially the same signal waveform that is generated by a single carrier transmitter 520 shown in the FIG. 6 which does not use FFT/IFFT processing.

In the single carrier transmitter 520 which does not use FFT/IFFT processing as shown in FIG. 6, a data modulator 401 converts the first data stream 301 to the first modulated data stream 402 and a CP adder 522 then adds a cyclic prefix having the same time length as that of the cyclic prefix added by the CP adder 309 of the OFDM transmitter 101 to the first modulated data stream 402.

The first modulated data stream 402 with the cyclic prefix added thereto is upsampled by an upsampling unit 520, subjected to waveform shaping on the time domain by a waveform shaping filter 521 and then transmitted from an antenna 525 through a D/A converter 523 and an RF/IF transmitter 524 in order. In this case, the frequency response of the waveform shaping filter 521 is equivalent to that of the waveform shaping filter 407 (FIG. 4) on the frequency domain.

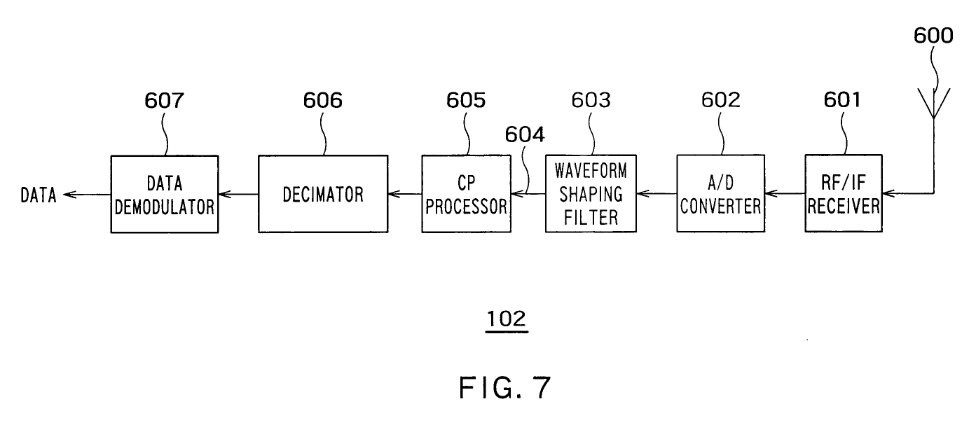

FIG. 7 illustrates a configuration example of the single carrier receiver 102 according to this embodiment. The received signal obtained by an antenna 600 is passed through an RF/IF receiver 601, converted to a digital signal by an A/D converter 602 and subjected to FIR filter processing on the time domain by a waveform shaping filter 603.

The waveform shaping filter 603 is a time-domain realization of the waveform shaping filter 407 on the frequency domain (FIG. 4) provided for the OFDM transmitter 101. That is, there is a relationship that the waveform shaping filter 603 on the time domain corresponds to the waveform shaping filter 407 on the frequency domain (FIG. 4) subjected to an inverse Fourier transform (IFFT transform). This waveform shaping filter 603 is also equivalent to the waveform shaping filter 521 (FIG. 6) of the single carrier transmitter 520.

Of a signal 604 which has passed through the waveform shaping filter, a CP processor 605 removes sample points having the same length as that of the cyclic prefix added by the CP adder 309 (FIG. 3) of the OFDM transmitter 101. Alternatively, the cyclic prefix is a copy of the end part of a transmission signal and the cyclic prefix part may also be combined with the end part in the signal 604.

A decimator 606 decimates the output of the CP processor 605 at a symbol rate of the first modulated data stream 402 generated in the single carrier modulator 302 of the OFDM transmitter 101. That is, the decimator 606 extracts sample values with the same number (N) of elements of the modulated data transmitted from the OFDM transmitter 101 within a 1 OFDM symbol time. Next, a data demodulator 607 demodulates the first data stream.

In this way, the single carrier signal multiplexed with the OFDM signal from the OFDM transmitter 101 can be demodulated using the single carrier receiver 102 in a simple configuration without performing FFT or IDFT processing.

Since aliasing occurs at parts of the head and the end of an OFDM symbol in the time waveform generated by the OFDM transmitter 101 having the single carrier modulator 302, the time waveform becomes different from the waveform generated by the single carrier transmitter 520 (FIG. 6).

This produces interference when the corresponding parts of the head and the end of an OFDM symbol are received by the single carrier receiver 102. Since the parts where such aliasing occurs are located within a certain range at both ends of the OFDM symbol, the influence of this distortion can be suppressed using the method shown below.

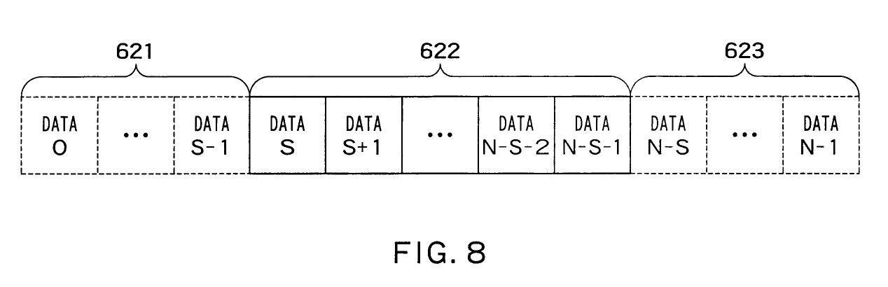

As shown in FIG. 8, the data part affected by interference can be eliminated by setting a part 621 at the head and a part 623 at the end of the first data stream 301 to “zero data” (null data). Alternatively, lowering the modulation order of the part 621 at the head and the part 623 at the end of the first data stream 301 compared to another data part 622 can make the data part at the head and at the end resistant to interference. The number of elements of data S (S is an integer equal to or greater than 1) added to the head and the end is normally a value half the length of time waveform in the waveform shaping filter 603.

As a method of avoiding the above described interference in addition to insertion of zero data in this way, the length of a cyclic prefix added by the CP adder 309 of the OFDM transmitter 101 may be simply extended by an extra portion corresponding to the time waveform of the waveform shaping filter 603, but in such a case, the efficiency of transmission of not only the data to the single carrier receiver 102 but also the data to the OFDM receiver 103 decreases.

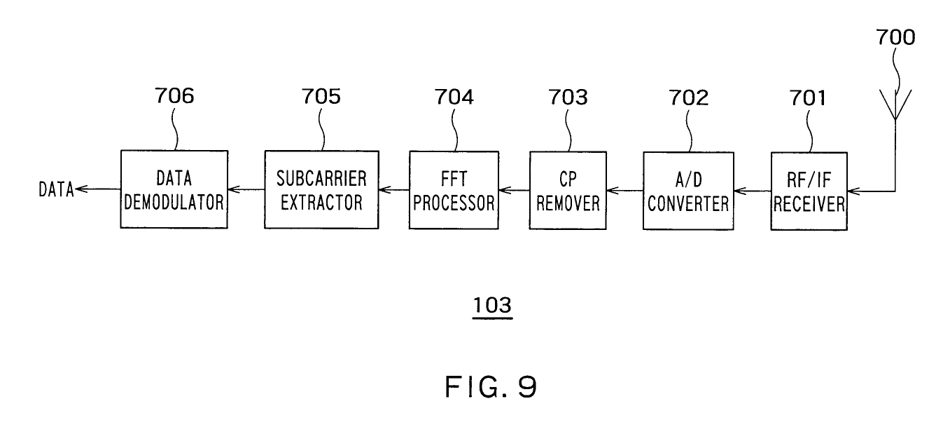

FIG. 9 illustrates a configuration example of the OFDM receiver 103 according to this embodiment. FIG. 9 shows the same configuration as the conventional OFDM receiver configuration. A received signal obtained by an antenna 700 is passed through an RF/IF receiver 701 and converted to a digital signal at an A/D converter 702. Of this digital signal, a cyclic prefix remover 703 removes sample points having the same length as that of the cyclic prefix added by the OFDM transmitter 101. An FFT processor 704 converts the output of the CP remover 703 to data on the frequency domain.

A subcarrier extractor 705 extracts the data of subcarriers to which the data to the OFDM receiver 103 is mapped from this data on the frequency domain. Next, a data demodulator 706 demodulates second data. In this case, the OFDM receiver 103 does not receive interference from the single carrier signal transmitted to the single carrier receiver 102 from the OFDM transmitter 101.

The above described configuration shows an embodiment related to the configuration of the radio communication system 100 made up of the single carrier receiver 102, the OFDM receiver 103 and the OFDM transmitter 101 which simultaneously transmits data to the single carrier receiver 102 and OFDM receiver 103.

Next, an uplink in a case where a radio signal is transmitted from an OFDM terminal and a single carrier terminal to an OFDM base station will be explained.

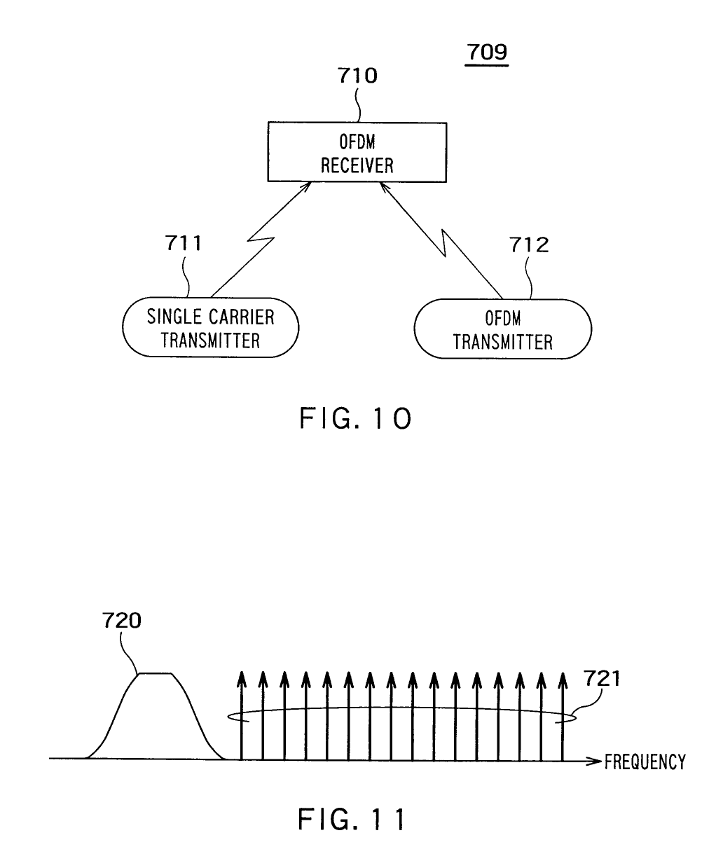

FIG. 10 illustrates a configuration example of a radio communication system 709 according to this embodiment and this radio communication system 709 includes a single carrier transmitter 711, an OFDM transmitter 712 and an OFDM receiver 710 which simultaneously receives a signal from the single carrier transmitter 711 and a signal from the OFDM transmitter 712.

As shown in FIG. 11, a signal from the single carrier transmitter 711 is transmitted in a partial band which is restricted by the filter 720 having a certain bandwidth and a signal from the OFDM transmitter 712 is transmitted to the OFDM receiver 710 using subcarriers (third subcarriers) 721 in a band different from that of the filter of the single carrier transmitter 711 (corresponding to a band occupied by fourth subcarriers).

Here, the single carrier transmitter 711 according to this embodiment will be explained using first to fourth configuration examples.

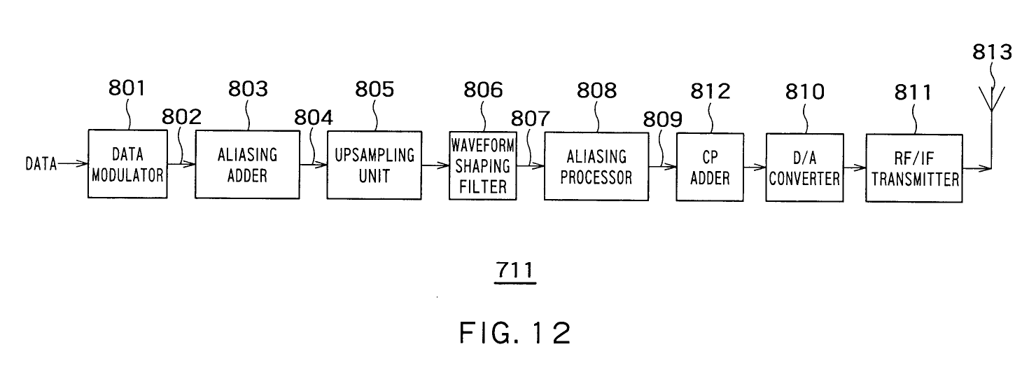

FIG. 12 illustrates a first configuration example of the single carrier transmitter 711 according to this embodiment. A data modulator 801 modulates a first data stream into a modulated data stream 802 of N (N is an integer equal to or greater than 1) elements of data. Next, an aliasing adder 803 (data expander) adds part of the modulated data stream to the head and the end thereof so as to repeat the modulated data stream 802.

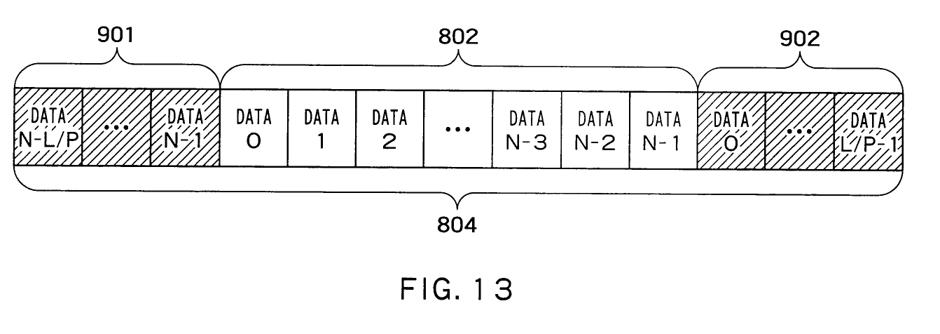

FIG. 13 shows a configuration example of an output data stream 804 at the aliasing adder 803. In FIG. 13, an L/P (“L” is such an integer that L/P becomes an integer equal to or greater than 1) symbol 901 is added to the head of a modulated data stream 802 having a length of N and an L/P symbol 902 is added to the end in the same way, resulting in an output data stream 804 having a length of N+2L/P from the aliasing adder 803.

An upsampling unit 805 upsamples the output data stream 804 from the aliasing adder 803 P times (P is an integer equal to or greater than 1), and thereby inserts (P−1) 0s per symbol, generates and outputs an output signal having a total length of P×N+2L.

Next, a waveform shaping filter 806 performs FIR filter processing whose number of taps (the number of filter factors) is 2L+1 (“L” is an integer equal to or greater than 0) on the time domain on the output signal from the upsampling unit 805.

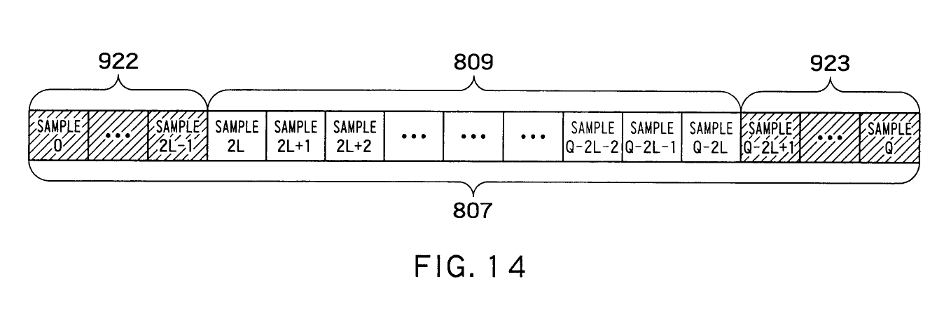

FIG. 14 illustrates the operation of an aliasing processor 808. The number of samples Q of an output signal 807 from the waveform shaping filter 806 is Q=P×N+4L and the aliasing processor 808 removes first 2L samples 922 and last 2L samples 923 from the output signal 807 of the waveform shaping filter 806. That is, a signal resulting from extracting P×N sample points in the center of the output signal 807 of the waveform shaping filter 806 become an output signal 809 of the aliasing processor 808.

A CP adder 812 copies the end of the output signal 809 from the aliasing processor 808 and adds it to the head of the output signal 809. The output signal of the CP adder 812 is converted to an analog signal at a D/A converter 810 and then transmitted from an antenna 813 through an RF/IF transmitter 811.

In this way, the influence of aliasing by the filter processing of the waveform shaping filter 806 is intentionally added by adding part of the modulated data stream to the head and the end thereof so as to repeat the modulated data stream 802 and then removing it. In this way, it is possible to generate a signal orthogonal to a signal from the OFDM transmitter 712 which will be described later.

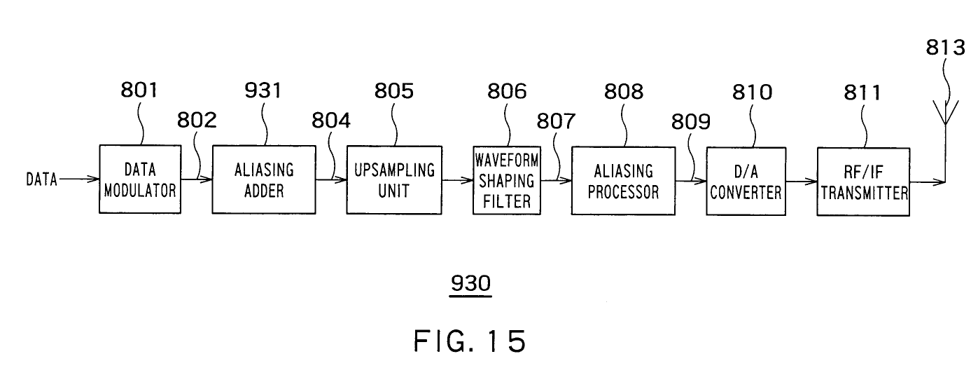

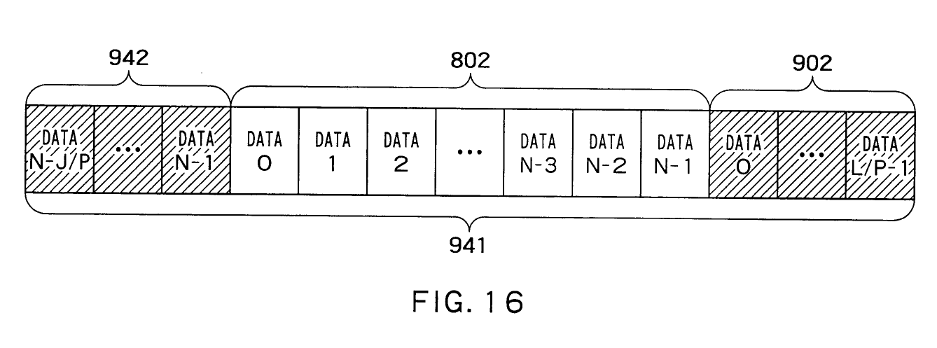

Next, a second configuration example of a single carrier transmitter 930 according to this embodiment is shown in FIG. 15. In the example of FIG. 15, the function of the CP adder 812 is absorbed by an aliasing adder 931. FIG. 16 illustrates the operation of the aliasing adder 931. The difference from FIG. 13 is in that data 942 added to the head of the modulated data stream 802 is longer by an extra portion corresponding to a cyclic prefix. The operations of the other parts of the single carrier transmitter 930 in FIG. 15 are basically the same as those of the single carrier transmitter 711 in FIG. 12.

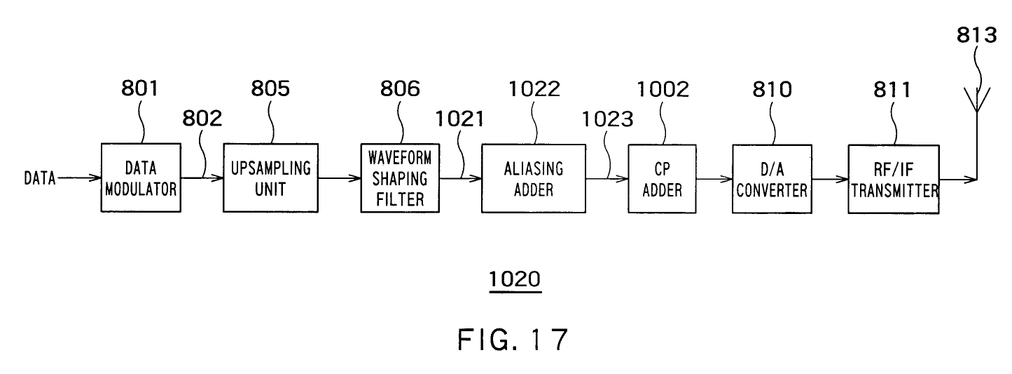

Next, a third configuration example of a single carrier transmitter 1020 according to this embodiment is shown in FIG. 17. The single carrier transmitter 1020 in FIG. 17 generates a transmission waveform equivalent to that of the single carrier transmitter 711 or 930 in FIG. 12 or FIG. 15.

In FIG. 17, a data modulator 801 modulates a first data stream into a modulated data stream 802 with N (N is an integer equal to or greater than 1) elements of data. An upsampling unit 805 upsamples the modulated data stream 802 P times (P is an integer equal to or greater than 1), and thereby inserts (P−1) 0s per symbol and generates and outputs an output signal having a total length of P×N.

Next, a waveform shaping filter 806 executes FIR filter processing whose number of taps is 2L+1 (L is an integer equal to or greater than 0) on the time domain for the output signal of the upsampling unit 805. The number of samples Q of an output signal 1021 of the waveform shaping filter 806 is Q=P×N+2L.

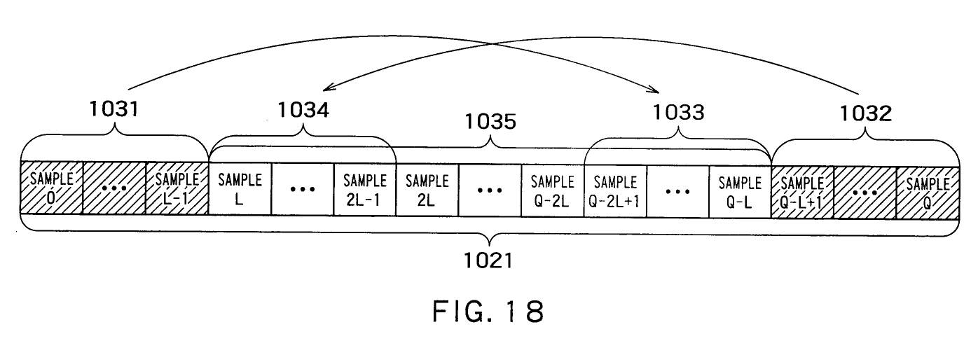

FIG. 18 illustrates the operation of an aliasing adder 1022. First L samples 1031 of the output signal 1021 from the waveform shaping filter 806 are added to a portion 1033 and last L samples 1032 are added to a portion 1034, a portion 1035 with P×N samples in the center of the whole is then extracted, resulting in an output signal 1023 from the aliasing adder. The operations of parts from the aliasing adder 1022 onward are the same as those in the case of the single carrier transmitter 711 in FIG. 12.

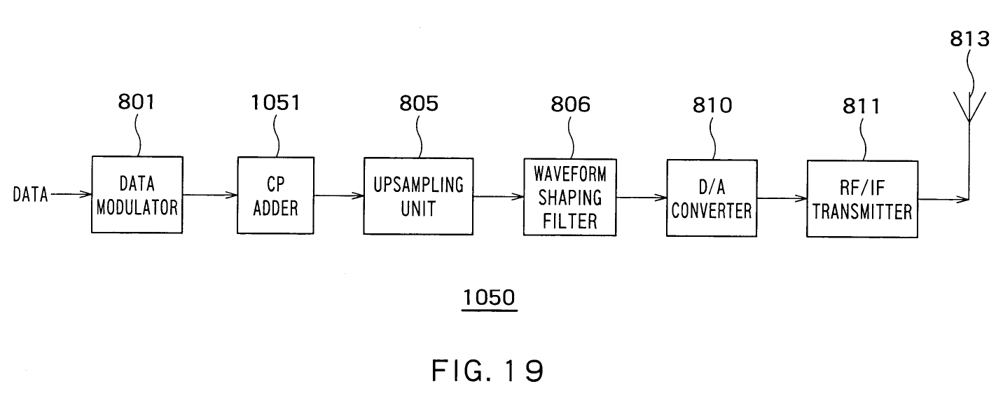

FIG. 19 shows a fourth configuration example of a single carrier transmitter 1050 according to this embodiment. In the configuration example in the same figure, there is neither aliasing processor nor aliasing adder. Therefore, in order to have a tolerance to the same multipath delay waves as those in the first to third configuration examples shown in FIG. 12, FIG. 15 and FIG. 17, the time length of a cyclic prefix added by a CP adder 1051 needs to be longer than that of the CP adder 1002 of FIG. 17 by the time response of a waveform shaping filter 806. The operations of other parts of the single carrier transmitter 1050 in FIG. 19 are basically the same as those of the single carrier transmitter 1020 in FIG. 17.

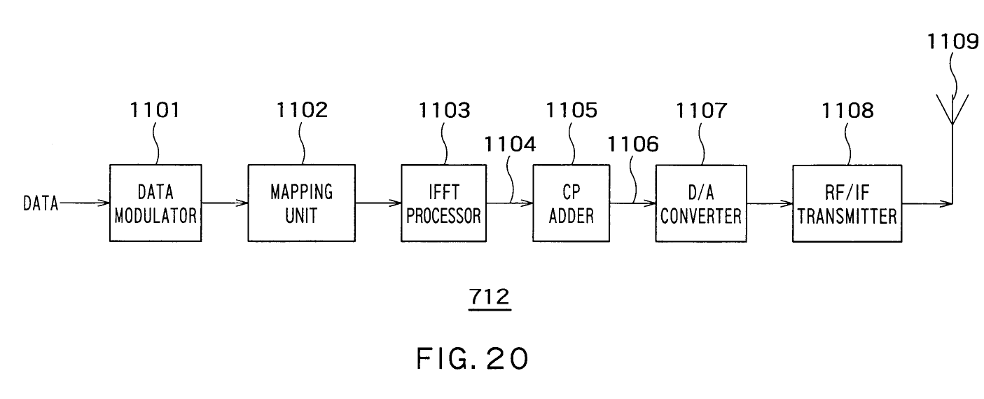

FIG. 20 illustrates a configuration example of an OFDM transmitter 712 according to this embodiment. A second data stream is modulated by a data modulator 1101 and converted to a modulated data stream. Next, the modulated data stream is mapped to subcarriers at a mapping unit 1102, and then subjected to IFFT processing at an IFFT processor 1103, resulting in an OFDM symbol 1104. Next, a CP adder 1105 adds the end of the OFDM symbol 1104 to the OFDM symbol 1104 and generates an OFDM symbol 1106 with a CP added. Next, this OFDM symbol 1106 is converted to an analog signal at a D/A converter 1107 and transmitted from an antenna 1109 through an RF/IF transmitter 1108.

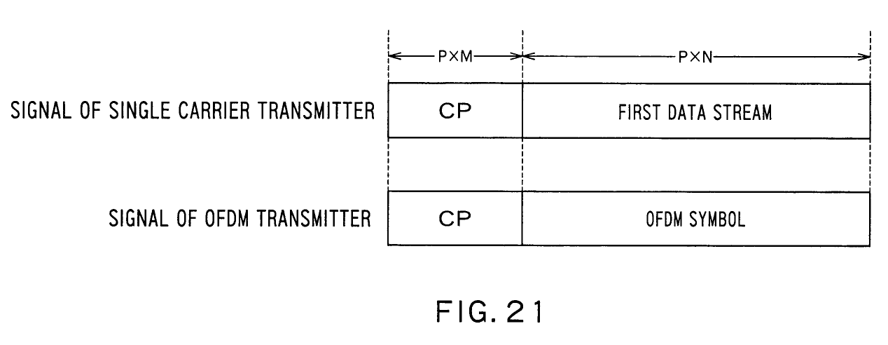

FIG. 21 illustrates a relationship between the length of the data stream of the single carrier transmitter 711 and the length of the OFDM symbol of the OFDM transmitter 712. The length N of the first data stream is equal to the length of 1 OFDM symbol. Furthermore, the lengths of the added CPs are also the same. That is, the length of the OFDM symbol 1104 is equal to the time of P×N samples in the output signal 809 of the aliasing processor 808 in FIG. 12 and the length of the OFDM symbol 1106 with a CP is equal to the time length of P×(N+M) samples of the output signal 809 at the aliasing processor in FIG. 12.

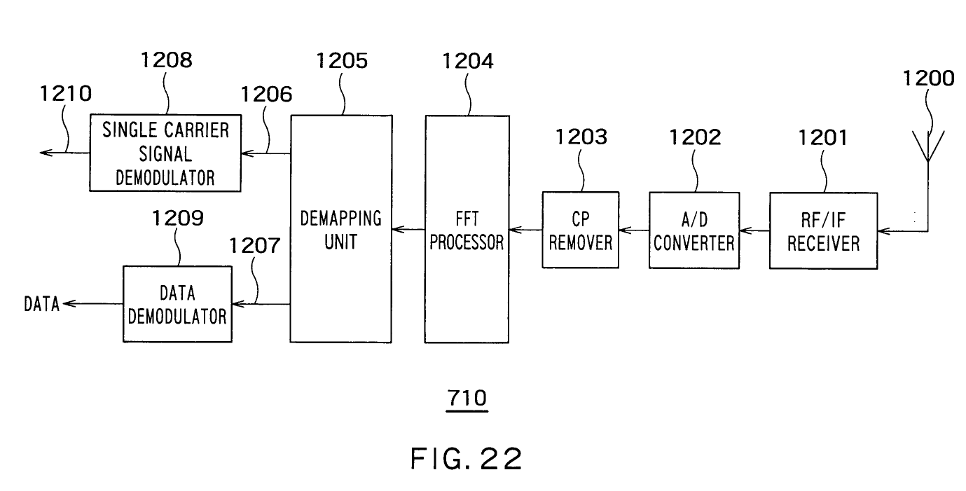

FIG. 22 illustrates a configuration example of the OFDM receiver 710 according to this embodiment, which simultaneously receives a signal from the single carrier transmitter 711 and a signal from the OFDM transmitter 712. This OFDM receiver 710 is a receiver which simultaneously receives a signal from any one of the single carrier transmitters 711, 930, 1020 and 1050 and a signal from the OFDM transmitter 712. In this case, suppose that the OFDM receiver 710 receives the signal from the single carrier transmitter 711 in synchronization with the signal from the OFDM transmitter 712 with a difference within the length of a cyclic prefix.

As shown in FIG. 22, a received signal received by an antenna 1200 is passed through an RF/IF receiver 1201 and converted to a digital signal at an A/D converter 1202. Of this digital signal, a CP remover 1203 removes sample points corresponding to the length of a cyclic prefix. An FFT processor 1204 converts an output signal output from the CP remover 1203 from a time domain signal to a frequency domain signal (frequency domain data).

A demapping unit 1205 (divider) divides the output signal of the FFT processor 1204 (frequency domain data) into single carrier received data (second frequency domain data) 1206 which are subcarriers in which the single carrier signal exists and OFDM received data (first frequency domain data) 1207 which are subcarriers in which the OFDM signal exists. That is, single carrier received data 1206 is allocated to subcarriers in the frequency range of the waveform shaping filter 806 in the single carrier transmitter 711.

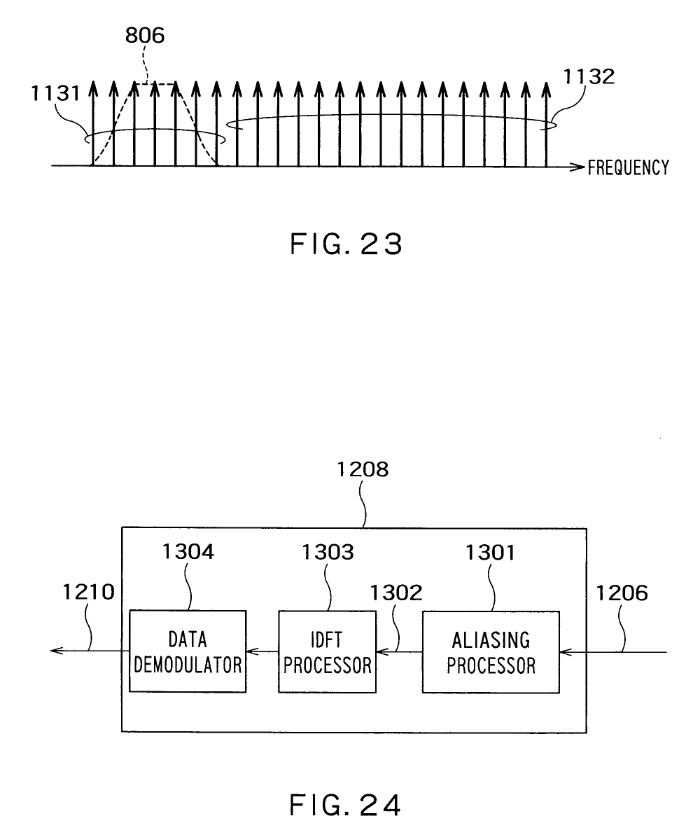

FIG. 23 illustrates an example of the single carrier received data 1206 and the OFDM received data 1207. In the same figure, subcarriers (fourth subcarriers) 1131 within the range of the waveform shaping filter 806 of the single carrier transmitter 711 correspond to the single carrier received data 1206 and subcarriers (third subcarriers) 1132 correspond to the OFDM received data in 1207.

The single carrier received data 1206 is demodulated at a single carrier demodulator (second demodulator) 1208 and the received data 1207 of the OFDM signal is demodulated at a data demodulator (first demodulator) 1209. In this case, the data demodulator 1209 may be subjected to equalization whereby each subcarrier is multiplied by a complex number to compensate for distortion in the communication path before making a data judgment.

FIG. 24 illustrates a configuration example of the single carrier signal demodulator 1208 of the OFDM receiver 710 according to this embodiment. Using the single carrier received data 1206, an aliasing processor 1301 combines the data of subcarriers having aliasing data which is out of the bandwidth of the symbol rate of the modulated data stream at the single carrier transmitter 711 into data of N subcarriers within the bandwidth of the symbol rate of the modulated data stream and thereby generates aliasing combined data.

The number of subcarriers within the bandwidth of the symbol rate is equal to the number (N) of elements of modulated data per 1 OFDM symbol time transmitted from the single carrier transmitter 711. Furthermore, the aliasing processor 1301 may also multiply each subcarrier by complex data for compensating for distortion of the channel before aliasing combining.

An output signal 1302 from the aliasing processor 1301 is subjected to IDFT processing at an IDFT processor 1303, resulting in a signal on the time domain. Next, an output signal from the IDFT processor 1303 is demodulated at a data demodulator 1304 and the first data stream transmitted from the single carrier transmitter 711 is judged and demodulated.

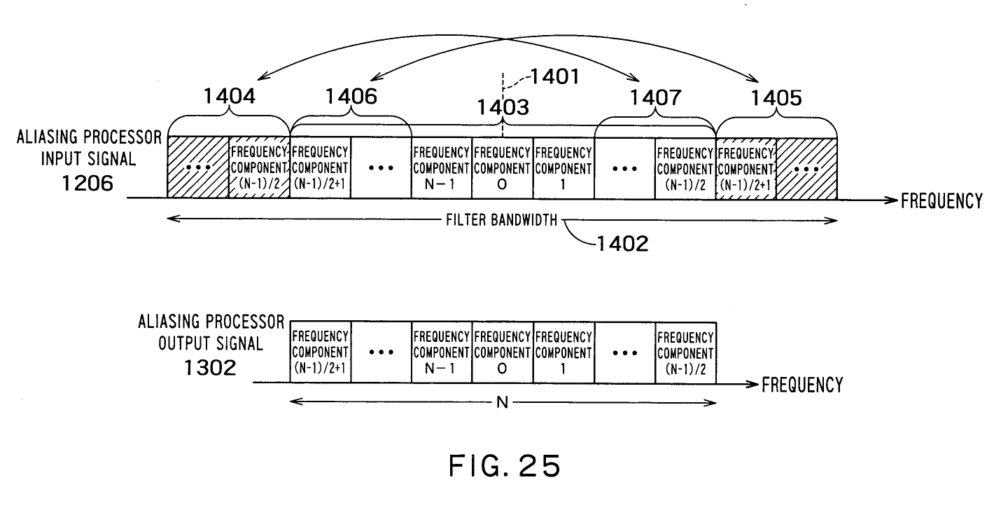

FIG. 25 shows an example of combining of subcarriers by the aliasing processor 1301. Subcarriers including a single carrier signal are determined according to a filter bandwidth 1402 of the waveform shaping filter 806 of the single carrier transmitter 711 centered on a central frequency 1401 of the single carrier signal.

N subcarriers (N is the number of elements of transmission data included in the first data stream of the single carrier transmitter 711) in the center of the subcarriers correspond to an original frequency data part 1403 and other subcarriers correspond to aliasing parts 1404 and 1405.

The aliasing parts 1404 and 1405 are generated in a structure whereby the original frequency data part 1403 is periodically repeated every N subcarriers and, for example, the aliasing part 1405 contains data which is equal to the frequency data part 1406, and likewise the aliasing part 1404 contains data which is equal to the frequency data part 1407. Because of the frequency characteristic of the waveform shaping filter 806 of the single carrier transmitter 711, amplitudes and phases of the frequency data part 1403 and the aliasing parts 1404 and 1405 change.

The aliasing processor 1301 combines the aliasing parts 1404 and 1405 and the original frequency data part 1403. When combining, it is preferable to perform maximum ratio combining whereby the respective parts are multiplied by a complex conjugate value of the frequency characteristic for each subcarrier of the waveform shaping filter 806 and then added up.

Suppose the square sum of coefficients when combining is normalized to 1. Alternatively, before combining the aliasing parts 1404 and 1405, the respective parts may also be multiplied by a complex number for each subcarrier to correct distortion in the communication path. Data corresponding to N subcarriers is outputted as the output signal 1302 from the aliasing processor 1301.

As described above, according to this embodiment, it is possible to realize the OFDM transmitter 101 which simultaneously transmits data to the single carrier receiver 102 and the OFDM receiver 103. It is also possible to realize the OFDM receiver 710 which can simultaneously receive signals from the single carrier transmitter 711 and the OFDM transmitter 712. Alternatively, it is also possible to realize a radio communication system made up of a single carrier transmitter/receiver, an OFDM transmitter/receiver and an OFDM transmitter/receiver which can simultaneously communicate with them.

What is claimed is:

1. A transmission apparatus comprising:
a first modulator configured to perform modulation processing on data to be transmitted to a first reception apparatus and thereby generate amplitude-phase data made up of data of amplitude and phase;
a second modulator configured to perform modulation processing so as to decompose data to be transmitted to a second reception apparatus into a plurality of frequency components and thereby generate frequency data which is data on a frequency domain; and
a transmitter configured to allocate the amplitude-phase data to first subcarriers used by the first reception apparatus out of a plurality of subcarriers and allocate the frequency data to second subcarriers used by the second reception apparatus which are different from the first subcarriers out of the plurality of subcarriers, thereby generate subcarrier data and transmit generated subcarrier data to the first reception apparatus and the second reception apparatus.

2. The apparatus according to claim 1, wherein the second modulator includes:
a data modulator configured to apply modulation processing to data to be transmitted to the second reception apparatus and thereby generate amplitude-phase data made up of data of amplitude and phase;
a Fourier transformer configured to perform a Fourier transform on the amplitude-phase data generated by the data modulator and thereby generate frequency domain data;
a data expander configured to expand the frequency domain data by adding part of the frequency domain data to the frequency domain data and thereby generate expanded data; and
a filter processor configured to multiply the expanded data by a filter factor and thereby generate the frequency data.

3. The apparatus according to claim 1, wherein part at a head and part at an end of the data to be transmitted to the second reception apparatus are zero data.

4. The apparatus according to claim 1, wherein a modulation multivalue number of part at a head and part at an end of the data to be transmitted to the second reception apparatus are lower than that of a data portion excluding the part at the head and the part at the end in the data.

5. The apparatus according to claim 1, wherein the second subcarriers to which the frequency data is allocated include subcarriers whose frequency position is located at an end in all the subcarriers.

6. A transmission apparatus comprising:
a data modulator configured to generate amplitude-phase data made up of data of amplitude and phase by applying modulation processing to data to be transmitted;
a data expander configured to generate expanded data by adding part of the amplitude-phase data to a head and an end of the amplitude-phase data to extend the amplitude-phase data;
an upsampling unit configured to obtain upsampled data by inserting predetermined data between symbols forming the expanded data to perform upsampling;
a filter processor configured to obtain filter processed data by performing waveform shaping filter processing on the upsampled data;
a remover configured to obtain removed data by removing parts at a head and an end of the filter processed data; and
an adder configured to copy part of an end of the removed data and adding copied part to a head of the removed data.

7. A transmission apparatus comprising:
a data modulator configured to generate amplitude-phase data made up of data of amplitude and phase by applying modulation processing to data to be transmitted;
an upsampling unit configured to obtain upsampled data by inserting predetermined data between symbols forming the amplitude-phase data to perform upsampling;
a filter processor configured to obtain filter processed data by performing waveform shaping filter processing on the upsampled data;
an adder configured to obtain addition data by adding parts at a head and an end of the filter processed data to specific data portion excluding the parts at the head and the end in the filter processed data; and
an adder configured to copy part at an end of the addition data and add copied part to a head of the addition data.

8. A reception apparatus comprising:
a Fourier transformer configured to obtain frequency domain data made up of a plurality of frequency components by performing a Fourier transform on a received signal;
a divider configured to divide the frequency domain data into first frequency domain data which corresponds to third subcarriers out of a plurality of subcarriers and second frequency domain data which corresponds to fourth subcarriers which are different from the third subcarriers out of the plurality of subcarriers;
a first demodulator configured to demodulate the first frequency domain data in a multicarrier scheme; and
a second demodulator configured to perform demodulation processing on the second frequency domain data to convert the second frequency domain data to data on a time domain.

9. The apparatus according to claim 8, wherein the second demodulator includes:
a combiner configured to obtain combined data by combining data allocated to several subcarriers out of the second frequency domain data and data allocated to subcarriers different from the several subcarriers out of the second frequency domain data;
an inverse Fourier transformer configured to obtain time domain combined data which is data on the time domain by performing an inverse Fourier transform on the combined data; and
a data demodulator configured to apply predetermined demodulation processing to the time domain combined data.

10. A radio communication system in which a base station using a multicarrier modulation scheme as a modulation scheme, a multicarrier terminal apparatus using the multicarrier modulation scheme, and a terminal apparatus using a single carrier modulation scheme are wirelessly connected, comprising:
wherein the base station includes;
a base station transmitter having
a first modulator configured to perform modulation processing on data to be transmitted to the multicarrier terminal apparatus and thereby generate amplitude-phase data made up of data of amplitude and phase,
a second modulator configured to perform modulation processing so as to decompose data to be transmitted to the terminal apparatus into a plurality of frequency components and thereby generate frequency data which is data on a frequency domain, and
a transmitter configured to allocate the amplitude-phase data to first subcarriers used by the multicarrier terminal apparatus out of a plurality of subcarriers and allocate the frequency data to second subcarriers by used the terminal apparatus which are different from the first subcarriers out of the plurality of subcarriers, thereby generate subcarrier data and transmit generated subcarrier data to the multicarrier terminal apparatus and the terminal apparatus,
a base station receiver having
a Fourier transformer configured to obtain frequency domain data made up of a plurality of frequency components by performing a Fourier transform on a received signal;
a divider configured to divide the frequency domain data into first frequency domain data which corresponds to third subcarriers used by the multicarrier terminal apparatus out of a plurality of subcarriers and second frequency domain data which corresponds to fourth subcarriers used by the terminal apparatus which are different from the third subcarriers out of the plurality of subcarriers;
a first demodulator configured to demodulate the first frequency domain data in a multicarrier scheme; and
a second demodulator configured to perform demodulation processing on the second frequency domain data to convert the second frequency domain data to data on a time domain,
the multicarrier terminal apparatus includes;
a multicarrier terminal transmitter
configured to obtain modulated data by performing modulation processing on data to be transmitted to the base station in the multicarrier modulation scheme,
configured to copy part of an end of the modulated data, add copied part to a head of the modulated data as a cyclic prefix and thereby obtain modulated data with the cyclic prefix, and
configured to transmit the modulated data with the cyclic prefix, and
a multicarrier terminal receiver configured to performing demodulation processing on a received signal from the base station in a multicarrier demodulation scheme corresponding to the multicarrier modulation scheme, and
the terminal apparatus includes;
a terminal transmitter having
a data modulator configured to generate amplitude-phase data made up of data of amplitude and phase by applying modulation processing to data to be transmitted to the base station;
a data expander configured to generate expanded data by adding part of the amplitude-phase data to a head and an end of the amplitude-phase data to extend the amplitude-phase data;
an upsampling unit configured to obtain upsampled data by inserting predetermined data between symbols forming the expanded data to perform upsampling;
a filter processor configured to obtain filter processed data by performing waveform shaping filter processing on the upsampled data;
a remover configured to obtain removed data by removing parts at a head and an end of the filter processed data; and
an adder configured to copy part of an end of the removed data and adding copied part to a head of the removed data as a cyclic prefix, and
a terminal receiver configured to performing predetermined demodulation processing on a received signal from the base staion, and
wherein a length of the cyclic prefix added by the adder of the terminal apparatus is equal to a length of the cyclic prefix added by the multicarrier terminal transmitter of the multicarrier terminal apparatus.

11. The system according to claim 10,
wherein the second modulator of the base station transmitter in the base station
generates amplitude-phase data made up of data of amplitude and phase by applying modulation processing to data to be transmitted to the terminal apparatus,
generates frequency domain data by performing a Fourier transform on the amplitude-phase data;
generates expanded data by adding part of the frequency domain data to the frequency domain data to expand the frequency domain data, and
generates the frequency data by multiplying the expanded data by a filter factor.

12. The system according to claim 10, wherein part at a head and part at an end of the data to be transmitted to the terminal apparatus are zero data.

13. The system according to claim 10, wherein a modulation multivalue number of part at a head and part at an end of the data to be transmitted to the terminal apparatus are lower than that of a data portion excluding the part at the head and the part at the end in the data.

14. The system according to claim 10, wherein the second subcarriers to which the frequency data is allocated include subcarriers whose frequency position is located at an end in all the subcarriers.
